(19) United States
(12) Patent Application Publication
(10) Pub. No.: US 2025/0112115 A1
(43) Pub. Date: Apr. 3, 2025

(54) SEMICONDUCTOR PACKAGE AND SEMICONDUCTOR DEVICE

(71) Applicant: Resonac Corporation, Tokyo (JP)

(72) Inventors: Masaki TAKAHASHI, Tokyo (JP); Hiroaki FUJITA, Tokyo (JP); Shinji SHIMAOKA, Tokyo (JP); Hirokazu NOMA, Tokyo (JP)

(21) Appl. No.: 18/729,041

(22) PCT Filed: Dec. 26, 2022
(86) PCT No.: PCT/JP2022/047802

§ 371 Date: Jul. 15, 2024

(30) Foreign Application Priority Data
Feb. 2, 2022 (JP) 2022-015094

(51) Int. Cl. H01L 23/373; H01L 23/14

(52) U.S. Cl. CPC H01L 23/3736; H01L 23/145

(57) ABSTRACT

The present embodiment relates to a semiconductor package including an organic substrate having a circuit, a semiconductor chip that is mounted on a part of one surface of the organic substrate, and is electrically connected to the circuit, and a metal plate that is adhered to the one surface of the organic substrate in at least a part of a region where the semiconductor chip is not mounted, and is not electrically connected to the circuit, a metal constituting the metal plate having an average thermal expansion coefficient at 30 to 260° C. of 3 to 15 ppm/° C.

### TECHNICAL FIELD

The present embodiment relates to a semiconductor package and a semiconductor device.

### BACKGROUND ART

In recent years, the speed and the capacity of signals used in electronic devices, such as computers, are being increased, and the integration degree and the functionalities of semiconductor packages used in the electronic devices are also being enhanced.

A semiconductor package is constituted by mounting a semiconductor chip formed of an inorganic compound, such as silicon, on an organic substrate containing a resin and the like, in which warpage may therefore occur due to the stress caused by the difference in thermal expansion coefficient between the semiconductor chip and the organic substrate in some cases. The warpage of the semiconductor package may be a factor deteriorating the connection reliability to a motherboard or the like, and therefore is desirably suppressed.

Effective methods of suppressing the warpage of the semiconductor package include a method of decreasing the thermal expansion of the organic substrate. The decrease of the thermal expansion of the organic substrate reduces the difference in thermal expansion coefficient between the semiconductor chip and the organic substrate, and thereby the stress causing warpage in the thermal history can be suppressed.

With the increase in multifunctionality of the semiconductor chip, a heat dissipation member is used for enhancing the heat dissipation capability of the semiconductor chip (see, for example, PTL 1). The heat dissipation member is generally constituted by a metal excellent in thermal conductivity, so as to enhance the heat dissipation capability, and simultaneously to function as a reinforcing member for correcting the warpage of the semiconductor package in some cases. In the following description, the member that is provided for the purpose of heat dissipation and reinforcement may be referred to as a “heat dissipation and reinforcement member”.

### CITATION LIST

### Patent Literature

PTL 1: JP 2017-126668 A

### SUMMARY OF INVENTION

With the increase in multifunctionality of the semiconductor chip in recent years, the size of an organic substrate for mounting the semiconductor chip is also increased. According to the investigations by the present inventors, it has been particularly found that in the case where a semiconductor chip is mounted on a part of the surface of a large organic substrate, there is an increased difference between the warpage amount of the semiconductor package at room temperature and the warpage amount thereof at the reflow temperature in mounting the semiconductor package on a motherboard. The increase in the change amount of warpage due to temperature may be a factor deteriorating the connection reliability of the semiconductor package, but is difficult to suppress sufficiently by the ordinary measures.

In view of the current circumstances described above, a problem to be solved by the present embodiment is to provide a semiconductor package that is suppressed in the change amount of warpage due to temperature, and a semiconductor device including the semiconductor package.

### Solution to Problem

As a result of the earnest investigations made by the present inventors for solving the problem, it has been found that the problem can be solved by the present embodiment described below.

Specifically, the present embodiment relates to the following items [1] to [13].
[1] A semiconductor package including
an organic substrate having a circuit,
a semiconductor chip that is mounted on a part of one surface of the organic substrate, and is electrically connected to the circuit, and
a metal plate that is adhered to the one surface of the organic substrate in at least a part of a region where the semiconductor chip is not mounted, and is not electrically connected to the circuit,
a metal constituting the metal plate having an average thermal expansion coefficient at 30 to 260° C. of 3 to 15 ppm/° C.
[2] The semiconductor package according to the item [1], in which the metal constituting the metal plate is one or more kind selected from the group consisting of an alloy of copper and tungsten, an alloy of copper and molybdenum, and a stainless steel.
[3] The semiconductor package according to the item [2], in which the alloy of copper and tungsten has a content of tungsten of 65 to 90% by mass.
[4] The semiconductor package according to the item [2] or [3], in which the alloy of copper and molybdenum has a content of molybdenum of 20 to 60% by mass.
[5] The semiconductor package according to any one of the items [2] to [4], in which the stainless steel has a content of chromium of 10 to 25% by mass.
[6] The semiconductor package according to any one of the items [1] to [5], in which the metal constituting the metal plate has a Young's modulus of 150 GPa or more.
[7] The semiconductor package according to any one of the items [1] to [6], in which the metal constituting the metal plate has a thermal conductivity coefficient of 20 W/m·K or more.
[8] The semiconductor package according to any one of the items [1] to [7], in which the metal plate has a thickness of 0.5 to 5 mm.
[9] The semiconductor package according to any one of the items [1] to [8], in which the organic substrate has an area in plan view of 900 mm² or more.
[10] The semiconductor package according to any one of the items [1] to [9], in which the organic substrate has a rectangular outline shape in plan view, and four edges of the organic substrate having a rectangular outline shape each have a length of 30 mm or more.
[11] The semiconductor package according to any one of the items [1] to [10], in which the metal plate has an opening in plan view, and the semiconductor chip is mounted on at least a part of the one surface of the organic substrate exposed through the opening.
[12] The semiconductor package according to the item [11], in which the metal plate has a rectangular frame form in plan view.
[13] A semiconductor device including the semiconductor package according to any one of the items [1] to [12], and a motherboard mounting the semiconductor package.

### Advantageous Effects of Invention

The present embodiment can provide a semiconductor package that is suppressed in the change amount of warpage due to temperature, and a semiconductor device including the semiconductor package.

### BRIEF DESCRIPTION OF DRAWINGS

FIG. 1 is a schematic illustration (a) in plan view showing one example of a semiconductor package of the present embodiment, and a schematic illustration (b) in cross sectional view showing the same.

FIG. 2 is a schematic illustration in cross sectional view showing one example of the semiconductor package of the present embodiment.

FIG. 3 is a schematic illustration in plan view describing an analyzed region for warpage of a semiconductor package in examples.

### DESCRIPTION OF EMBODIMENTS

In the description herein, the numerical range shown by using “to” means a range that encompasses the numerical values shown before and after “to” as the minimum value and the maximum value.

For example, the expression of a numerical range of “X to Y” (in which X and Y each represent a real number) means a numerical range of X or more and Y or less. In the description herein, the expression of “X or more” means X and a value exceeding X. In the description herein, the expression of “Y or less” means Y and a value of less than Y.

In the description herein, the lower limit values and the upper limit values of the numerical ranges each can be optionally combined with each of the lower limit values and the upper limit values of the other numerical ranges.

In the description herein, the lower limit values and the upper limit values of the numerical ranges each can be replaced by each of the values described in the examples.

In the description herein, the “rectangular shape” means a concept that encompasses a complete rectangular shape and an approximately rectangular shape. The “approximately rectangular shape” encompasses, for example, a rectangular shape including a curve in at least a part of the edge thereof, a rectangular shape having a round corner, and the like.

The functional mechanisms shown in the description herein are estimation, and do not restrict the mechanism exhibiting the effects of the present embodiment.

Embodiments obtained by optionally combining the matters shown in the description herein are also encompassed in the present embodiment.

### [Semiconductor Package]

The semiconductor package of the present embodiment includes
an organic substrate having a circuit,
a semiconductor chip that is mounted on a part of one surface of the organic substrate, and is electrically connected to the circuit, and
a metal plate that is adhered to the one surface of the organic substrate in at least a part of a region where the semiconductor chip is not mounted, and is not electrically connected to the circuit, and
a metal constituting the metal plate has an average thermal expansion coefficient at 30 to 260° C. of 3 to 15 ppm/° C.

The mechanism that suppresses the change amount of warpage due to temperature in the semiconductor package of the present embodiment is not clear, but can be estimated as follows.

For suppressing the warpage of the semiconductor package, it is necessary to allow the thermal expansion coefficient of the organic substrate to be close to the thermal expansion coefficient of the semiconductor chip. In particular, in the case where the semiconductor chip is mounted on a part of the surface of the large organic substrate, even though the warpage of a region having the semiconductor chip mounted thereon is relatively small, the influences thereof on the entire shape of the organic substrate becomes large, and therefore a higher level of reduction in thermal expansion is required for the organic substrate. However, in the case where the heat dissipation and reinforcement member described above is adhered to the organic substrate, the reduction in thermal expansion of the organic substrate leads to a problem in the region where the semiconductor chip is not mounted in which the change amount of warpage due to temperature of the entire semiconductor package is increased due to the difference in thermal expansion coefficient between the organic substrate and the heat dissipation and reinforcement member. Furthermore, in the case where the heat dissipation and reinforcement member is provided also on the surface of the semiconductor chip, a stress occurs due to the difference in thermal expansion coefficient between the semiconductor chip and the heat dissipation and reinforcement member or the adhesive therefor, and thereby it becomes more difficult to control the change amount of warpage due to temperature.

On the other hand, the semiconductor package of the present embodiment uses a metal plate constituted by a metal having an average thermal expansion coefficient at 30 to 260° C. of 3 to 15 ppm/° C. as the heat dissipation and reinforcement member. The average thermal expansion coefficient of the metal plate is close to the thermal expansion coefficient of the organic substrate, and therefore the stress due to the difference in thermal expansion coefficient between the metal plate and the organic substrate can be suppressed from occurring. Furthermore, the metal plate is adhered to the region where the semiconductor chip is not mounted, and therefore the stress due to the difference in thermal expansion coefficient between the semiconductor chip and the metal plate or the adhesive therefor can also be suppressed from occurring. It is estimated that consequently the influence of the change amount of warpage due to temperature in the region where the semiconductor chip is mounted can be suppressed, and simultaneously the change amount of warpage due to temperature in the region where the semiconductor chip is not mounted can efficiently suppressed.

The present embodiment will be described below with reference to the drawing.

In the figures used in the description herein, the important part is enlarged or simplified for convenience. Therefore, the dimensional ratios, the numbers, and the like of the constitutional elements are not necessarily the same as the actual products.

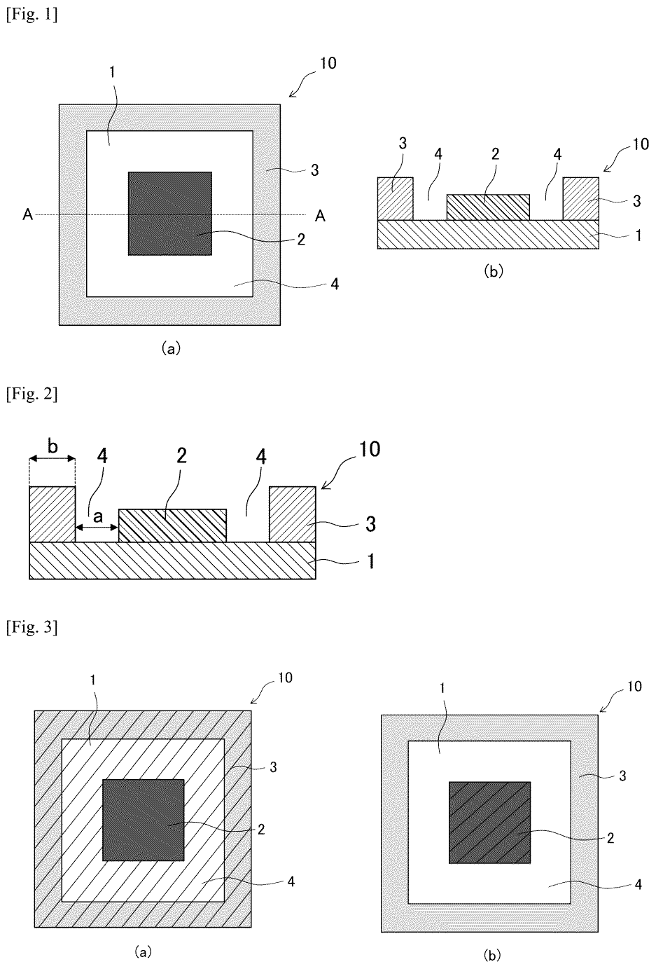

FIG. 1(a) is a schematic illustration in plan view of a semiconductor package 10 as one embodiment of the present embodiment, and FIG. 1(b) is a schematic illustration in cross sectional view of the semiconductor package 10 on the cross section A-A in FIG. 1(a). FIG. 2 is the same as the schematic illustration in cross sectional view of the semiconductor package 10 shown in FIG. 1(b), in which symbols are indicated for describing the distances.

The semiconductor package 10 includes an organic substrate 1 having a circuit, a semiconductor chip 2, and a metal plate 3.

### <Organic Substrate 1 Having Circuit>

The organic substrate 1 having a circuit (which may be hereinafter referred simply to as an “organic substrate 1”) is a substrate having a circuit and an insulating layer containing an organic component.

Examples of the insulating layer include an insulating layer formed of a cured product of one or more kind selected from the group consisting of a prepreg obtained by impregnating a fiber substrate with a thermosetting resin composition, and a resin film formed by using a thermosetting resin composition.

Examples of the structure of the organic substrate 1 include a structure including a core layer formed by curing one ply of a prepreg or a laminate of two or more prepregs, having formed on one or both surfaces thereof a circuit, and a structure including the core layer above or the core layer above having the circuit formed thereon, having on one or both surfaces thereof a buildup layer including insulating layers, which each are a cured product of a prepreg or a resin film, and circuits, which are laminated alternately. The organic substrate 1 may be a core-less substrate formed of the buildup layer without a core layer.

The core layer used may be copper-clad laminates, “MCL-E-679FG”, “MCL-E-700G®”, “MCL-E-705G”, and “MCL-E-795G”, trade names, available from Showa Denko Materials Co., Ltd., or may be formed through heat and pressure press of a prepreg. Examples of the prepreg used for forming the core layer include “GEA-679FG”, “GEA-700G®”, “GEA-705G”, and “GEA-795G”, trade names, available from Showa Denko Materials Co., Ltd.

As the prepreg and the resin film used for forming the buildup layer, examples of the prepreg include “GEA-679 series”, “GEA-700G®”, “GEA-705G”, “GEA-795G”, “GEA-78G”, “GH-100”, “GH-200”, “AS-400HS”, “GWA-900G”, and “GW-910G”, trade names, available from Showa Denko Materials Co., Ltd., and examples of the resin film include ABF (Ajinomoto Buildup Film) series, “GX92”, and “GX-T31”, available from Ajinomoto Fine-Techno Co., Inc.

As for the prepregs and the resin films, one kind thereof may be used alone, or two or more kinds thereof may be used in combination.

The average thermal expansion coefficient in the plane direction at 30 to 260° C. of the insulating layer of the organic substrate 1 is preferably 3 to 16 ppm/° C., more preferably 4 to 15 ppm/° C., further preferably 5 to 14 ppm/° C., and still further preferably 6 to 12 ppm/° C., and may be 7 to 9 ppm/° C., from the standpoint of suppressing the warpage due to the difference in thermal expansion coefficient from the semiconductor chip.

The average thermal expansion coefficient of the insulating layer can be measured by the method shown in the examples.

The organic substrate 1 may have a via hole, a through hole, and the like, depending on necessity.

The via hole, the through hole, and the like can be formed by making a hole in the insulating layer, for example, with a drill, laser, or plasma.

The circuit of the organic substrate 1 may be a circuit formed by processing a metal foil laminated on the insulating layer, or a circuit formed by a plating method.

Examples of the plating method include an electroless plating method and an electroplating method.

Examples of the metal for plating include copper, gold, silver, nickel, platinum, molybdenum, ruthenium, aluminum, tungsten, iron, titanium, chromium, and alloys containing at least one kind selected from these metal elements. Among these, copper is preferred.

The method of forming the circuit may be known processes, such as a subtractive process, a full additive process, a semi-additive process (SAP), and a modified semi-additive process (m-SAP).

The organic substrate 1 may have a solder resist layer as the outermost layer depending on necessity.

The solder resist layer can be formed, for example, by a method of coating a solder resist, which is a photosensitive resin composition, on the insulating layer and the circuit, followed by exposing with light.

Examples of the solder resist include “SR7300” and “SR-F”, trade names, available from Showa Denko Materials Co., Ltd.

The thickness of the solder resist layer is not particularly limited, and is preferably 5 to 40 μm, more preferably 7 to 30 μm, and further preferably 10 to 25 μm, from the standpoint of the reliability and the reduction in thickness.

The organic substrate 1 has an electrode (which is not shown in the figures) for electrically connecting the semiconductor chip 2 and the circuit, on the surface on the side having the semiconductor chip 2 mounted thereon.

The organic substrate 1 has an electrode (which is not shown in the figures) for electrically connecting the circuit of the organic substrate 1 and a motherboard, on the surface on the opposite side of the surface on the side having the semiconductor chip 2 mounted thereon.

These electrodes are formed, for example, with the same material as the metal for plating described above.

The thickness of the organic substrate 1 is not particularly limited, and is preferably 0.1 to 5 mm, more preferably 0.3 to 3 mm, and further preferably 0.5 to 2 mm, from the standpoint of the processability and the handleability.

The thickness of the organic substrate 1 does not include the thickness of the electrode formed on the surface thereof.

The organic substrate 1 has a rectangular outline shape in plan view.

The lengths of the four edges of the organic substrate 1 having a rectangular outline shape in plan view are not particularly limited, and each are preferably 30 mm or more, more preferably 40 mm or more, and further preferably 50 mm or more, from the standpoint of the increase in multifunctionality and size of the semiconductor package. The lengths of the four edges of the organic substrate 1 having a rectangular outline shape in plan view are not particularly limited, and each may be 150 mm or less, may be 120 mm or less, may be 100 mm or less, and may be 70 mm or less, from the standpoint of the increase in size of the semiconductor package.

The outline shape of the organic substrate having a rectangular outline shape in plan view may be either a square shape or an oblong shape, and is preferably a square shape.

The outline shape in plan view of the organic substrate of the semiconductor package of the present embodiment is not limited to a rectangular shape, and may be any shape depending on the desired functions and the like, for example, a shape including a rectangular shape having protruding parts and depressed parts on the side edge thereof, and a shape having a notched side edge.

The area in plan view of the organic substrate 1 is not particularly limited, and is preferably 900 mm² or more, more preferably 1,600 mm² or more, and further preferably 2,500 mm² or more, from the standpoint of the increase in multifunctionality and size of the semiconductor package. The area in plan view of the organic substrate 1 is not particularly limited, and may be 22,500 mm² or less, may be 14,400 mm² or less, may be 10,000 mm² or less, and may be 4,900 mm² or less, from the standpoint of the increase in size of the semiconductor package.

### <Semiconductor Chip 2>

The semiconductor chip 2 is mounted on one surface of the organic substrate 1, and is electrically connected to the circuit of the organic substrate 1.

In the present embodiment, the semiconductor chip means a chip of semiconductor obtained by cutting a wafer having formed on the surface thereof integrated circuits each constituted by circuit elements, such as a transistor, a resistance, and a capacitor.

Examples of the material of the semiconductor chip 2 include an elemental semiconductor formed of a single element, such as silicon and germanium, and a compound semiconductor, such as gallium arsenide, gallium phosphide, indium phosphide, and silicon carbide.

The semiconductor chip 2 has bumps for connecting to the electrode of the substrate, formed on the surface having the circuit formed thereon.

Examples of the bumps include solder balls, bumps each including a copper post having solder disposed at an end thereof, and gold stud bumps.

The material of the solder is preferably alloy solder of tin, silver, copper, or the like, from the standpoint of the connection reliability and the environmental protection. Preferred specific examples thereof include lead-free solder, such as SnAgCu base, SnCu base, SnAg base, SnAgCuBi base, SnZnBi base, and SnAgInBi base.

The height of the bumps is not particularly limited, and for example, may be 10 to 300 μm.

The gap at the joint between the semiconductor chip 2 and the organic substrate 1 may be sealed with a liquid sealant from the standpoint of the reliability.

The semiconductor chip 2 has a rectangular shape in plan view.

The shape of the semiconductor chip having a rectangular shape in plan view may be either a square shape or an oblong shape, and is preferably a square shape.

The shape in plan view of the semiconductor chip of the semiconductor package of the present embodiment is not limited to a rectangular shape, and may be any shape other than a rectangular shape depending on the desired functions and the like.

The lengths of the four edges of the semiconductor chip 2 having a rectangular shape in plan view are determined depending on the desired functions and the like, and for example, each may be 5 to 100 mm, may be 10 to 80 mm, may be 12 to 60 mm, may be 15 to 50 mm, may be 18 to 40 mm, and may be 20 to 30 mm.

The thickness of the semiconductor chip 2 is determined depending on the desired functions and the like, and for example, may be 0.1 to 5 mm, may be 0.3 to 3 mm, and may be 0.5 to 1 mm.

The thickness of the semiconductor chip 2 does not include the thickness of the bumps.

In the semiconductor package 10, only one semiconductor chip 2 is mounted on one surface of the organic substrate 1, but the semiconductor package of the present embodiment is not limited to this configuration, and two or more semiconductor chips may be mounted on one surface of the organic substrate depending on the desired performance and the like. For example, the semiconductor package of the present embodiment may have an embodiment including two or more semiconductor chips mounted inside an opening 4 of the metal plate 3 of the semiconductor package 10 shown in FIGS. 1(a) and 1(b).

In the semiconductor package 10, the semiconductor chip 2 is exposed on the organic substrate 1, but the semiconductor chip of the semiconductor package of the present embodiment may be sealed entirely or partially with a semiconductor sealant depending on the desired functions and the like.

In the semiconductor package 10, the semiconductor chip 2 is mounted on the center of the organic substrate 1, but the semiconductor package of the present embodiment may include the semiconductor chip mounted on the other position than the center of the organic substrate depending on the desired functions and the like.

### <Metal Plate 3>

The metal plate 3 is adhered to the one surface of the organic substrate 1 in at least a part of the region where the semiconductor chip 2 is not mounted, and is not electrically connected to the circuit of the organic substrate 1.

The metal plate 3 is a metal plate constituted by a metal having an average thermal expansion coefficient at 30 to 260° C. of 3 to 15 ppm/° C.

The metal plate 3 is formed of a metal, and therefore has an excellent heat dissipation capability enhancing the heat dissipation capability of the semiconductor package, and simultaneously has a function of correcting the warpage of the semiconductor package 10 by the rigidity thereof. Furthermore, the metal plate 3 has a reduced difference in thermal expansion coefficient from the organic substrate 1, and therefore the semiconductor package having the metal plate 3 has a suppressed change amount of warpage due to temperature.

The average thermal expansion coefficient at 30 to 260° C. of the metal constituting the metal plate 3 is 3 to 15 ppm/° C., preferably 4 to 15 ppm/° C., more preferably 5 to 14 ppm/° C., and further preferably 6 to 13 ppm/° C., and may be 6 to 9 ppm/° C., from the standpoint of suppressing the change amount of warpage due to temperature more favorably.

The average thermal expansion coefficient at 30 to 260° C. of the metal can be measured by the method described in the examples.

The difference between the average thermal expansion coefficient at 30 to 260° C. of the metal constituting the metal plate 3 and the average thermal expansion coefficient in the plane direction at 30 to 260° C. of the organic substrate 1 ((average thermal expansion coefficient of metal)−(average thermal expansion coefficient of organic substrate 1)) is preferably-5 to 10 ppm/° C., more preferably-4 to 5 ppm/° C., further preferably-3 to 4 ppm/° C., still further preferably-2 to 3 ppm/° C., and particularly preferably-1 to 2 ppm/° C., from the standpoint of suppressing the change amount of warpage due to temperature more favorably.

The metal plate 3 is preferably a copper alloy or a stainless steel, more preferably one or more kind selected from the group consisting of an alloy of copper and tungsten, an alloy of copper and molybdenum, and a stainless steel, and further preferably an alloy of copper and tungsten, from the standpoint of suppressing the change amount of warpage due to temperature more favorably.

The content of tungsten in the alloy of copper and tungsten is not particularly limited, and is preferably 65 to 90% by mass, more preferably 70 to 87% by mass, and further preferably 75 to 85% by mass, from the standpoint of suppressing the change amount of warpage due to temperature more favorably, and the standpoint of the heat dissipation capability.

The total content of copper and tungsten in the alloy of copper and tungsten is not particularly limited, and is preferably 95 to 100% by mass, more preferably 97 to 100% by mass, further preferably 99 to 100% by mass, and particularly preferably 99.9 to 100% by mass, from the standpoint of suppressing the change amount of warpage due to temperature more favorably.

The content of molybdenum in the alloy of copper and molybdenum is not particularly limited, and is preferably 20 to 60% by mass, more preferably 25 to 55% by mass, and further preferably 30 to 50% by mass, from the standpoint of suppressing the change amount of warpage due to temperature more favorably, and the standpoint of the heat dissipation capability.

The total content of copper and molybdenum in the alloy of copper and molybdenum is not particularly limited, and is preferably 95 to 100% by mass, more preferably 97 to 100% by mass, further preferably 99 to 100% by mass, and particularly preferably 99.9 to 100% by mass, from the standpoint of suppressing the change amount of warpage due to temperature more favorably.

The content of chromium in the stainless steel is not particularly limited, and is preferably 10 to 25% by mass, more preferably 12 to 22% by mass, and further preferably 16 to 18% by mass, from the standpoint of suppressing the change amount of warpage due to temperature more favorably.

The content of iron in the stainless steel is not particularly limited, and is preferably 70 to 90% by mass, more preferably 74 to 88% by mass, further preferably 77 to 86% by mass, and particularly preferably 80 to 85% by mass, from the standpoint of suppressing the change amount of warpage due to temperature more favorably.

The Young's modulus of the metal constituting the metal plate 3 is not particularly limited, and is preferably 150 GPa or more, more preferably 160 GPa or more, further preferably 180 GPa or more, still further preferably 200 GPa or more, and particularly preferably 250 GPa or more, from the standpoint of suppressing the change amount of warpage due to temperature more favorably. The upper limit of the Young's modulus of the metal constituting the metal plate 3 is not particularly limited, and may be 1,000 GPa or less, may be 600 GPa or less, and may be 400 GPa or less, from the standpoint of the processability and the availability.

The Young's modulus of the metal can be measured by the method described in the examples.

The thermal conductivity coefficient of the metal constituting the metal plate 3 is not particularly limited, and is preferably 20 W/m·K or more, more preferably 100 W/m K or more, further preferably 150 W/m·K or more, still further preferably 170 W/m·K or more, and particularly preferably 190 W/m·K or more, from the standpoint of the heat dissipation capability. The thermal conductivity coefficient of the metal constituting the metal plate 3 is not particularly limited, and may be 500 W/m·K or less, may be 400 W/m K or less, and may be 300 W/m·K or less, from the standpoint of the availability.

The thermal conductivity coefficient of the metal can be measured by the method described in the examples.

The thickness of the metal plate 3 is not particularly limited, and is preferably 0.5 to 5 mm, more preferably 1 to 3.5 mm, and further preferably 1.5 to 2.5 mm, from the standpoint of suppressing the change amount of warpage due to temperature more favorably, and the standpoint of the reduction in weight.

The metal plate 3 may be subjected to a surface treatment for rust inhibition or the like, such as plating, depending on necessity.

The metal plate 3 of the semiconductor package 10 has a rectangular outline shape in plan view.

The lengths of the four edges of the metal plate 3 having a rectangular outline shape in plan view are determined depending on the size of the organic substrate, the desired functions, and the like, and for example, each may be 30 to 150 mm, may be 40 to 120 mm, may be 45 to 100 mm, and may be 50 to 70 mm, in such a range that fits within the surface of the organic substrate.

The outline shape of the metal plate having a rectangular outline shape in plan view may be either a square shape or an oblong shape, and is preferably a square shape.

The outline shape in plan view of the metal plate of the semiconductor package of the present embodiment is not limited to a rectangular shape, and may be any shape depending on the desired functions and the like, for example, a shape including a rectangular shape having protruding parts and depressed parts on the side edge thereof, and a shape having a notched side edge.

The metal plate 3 of the semiconductor package 10 has the opening 4 in plan view.

The semiconductor package of the present embodiment preferably has an embodiment in which the metal plate has an opening in plan view, and the semiconductor chip is mounted on at least a part of the one surface of the organic substrate exposed through the opening, from the standpoint of suppressing the change amount of warpage due to temperature more favorably.

In the semiconductor package 10, the semiconductor chip 2 is mounted inside the opening 4 in plan view, and as a result, the metal plate 3 is provided to surround continuously the periphery of the semiconductor chip 2.

In the semiconductor package of the present embodiment, the metal plate is preferably provided to surround continuously the periphery of the semiconductor chip in plan view, as in the semiconductor package 10, from the standpoint of suppressing the change amount of warpage due to temperature more favorably. However, the metal plate may not surround continuously the periphery of the semiconductor chip, depending on the desired functions and the like.

The opening 4 of the metal plate 3 has a rectangular shape in plan view.

The lengths of the four edges of the opening 4 having a rectangular shape in plan view are determined depending on the size of the semiconductor chip, the desired functions, and the like, and for example, each may be 27 to 90 mm, may be 28 to 85 mm, may be 30 to 80 mm, may be 33 to 59 mm, may be 35 to 55 mm, and may be 40 to 50 mm, in such a range that the semiconductor chip fits within the opening.

The shape of the opening having a rectangular shape in plan view may be either a square shape or an oblong shape, and is preferably a square shape.

The shape in plan view of the opening is not limited to a rectangular shape, and may be any shape depending on the desired functions and the like.

In the semiconductor package 10, the edge of the semiconductor chip 2 and the periphery of the opening 4 of the metal plate 3 have a substantially constant interval. In other words, the semiconductor chip 2 is mounted at the center of the opening 4 of the metal plate 3. The distance between the edge of the semiconductor chip 2 and the periphery of the opening 4 of the metal plate 3 (i.e., the distance a in FIG. 2) is determined depending on the desired functions and the like, and for example, may be 1 to 17 mm, may be 5 to 13 mm, may be 8 to 12 mm, and may be 9 to 10 mm.

However, in the semiconductor package of the present embodiment, the edge of the semiconductor chip and the periphery of the opening of the metal plate having the opening may not necessarily have a substantially constant interval, and intervals having different sizes may be provided, or an embodiment having substantially no interval may also be used, depending on the desired functions and the like.

The outline shape of the metal plate 3 and the shape of the opening 4 of the metal plate 3 are all rectangular shapes in plan view as described above, and thereby the shape in plan view of the metal plate 3 is a rectangular frame form. It is preferred that the edges constituting the outline shape of the metal plate 3 and the edges constituting the periphery of the opening 4 corresponding thereto each are in parallel to each other, and the width of the four sides constituting the rectangular frame form (i.e., the distance b in FIG. 2) is constant.

The width of the four sides constituting the rectangular shape of the metal plate 3 having a rectangular frame form in plan view (i.e., the distance b in FIG. 2) are determined depending on the desired functions and the like, and for example, each may be 1 to 20 mm, may be 2 to 19 mm, may be 3 to 18 mm, may be 4 to 17 mm, may be 5 to 14 mm, and may be 6 to 10 mm.

In the semiconductor package of the present embodiment, the width of the four sides constituting the rectangular shape of the metal plate having a rectangular frame form in plan view are not necessarily constant, and different widths may be provided depending on the desired functions and the like.

On one surface of the organic substrate 1 in plan view, the ratio of the area having the metal plate 3 adhered thereto to the total area (100%) where the semiconductor chip 2 is not mounted is preferably 8 to 98%, more preferably 15 to 90%, further preferably 30 to 80%, and still further preferably 40 to 75%, and may be 50 to 60%, from the standpoint of suppressing the change amount of warpage due to temperature more favorably.

In the semiconductor package 10, the organic substrate 1 and the metal plate 3 have the same outline shape in plan view, and the positions of the edges of the outline shapes in plan view thereof coincide with each other.

From the standpoint of enhancing the function as a heat dissipation and reinforcement member, an embodiment in which the positions of the edges of the organic substrate and the metal plate coincide with each other in plan view is preferred, an embodiment in which the metal plate is adhered from the edge in plan view of the organic substrate or a position apart from the edge thereof by 5 mm or less or 2 mm or less as the starting point toward the interior of the organic substrate is more preferred, and an embodiment in which the metal plate is adhered from all the edges in plan view of the organic substrate or positions apart from all the edges thereof by 5 mm or less or 2 mm or less as the starting point toward the interior of the organic substrate is further preferred.

The shape in plan view, the adhered position, the area, and the like of the metal plate are not limited to the examples above, and may be appropriately regulated depending on the desired functions and the like.

### <Production Method of Semiconductor Package>

The production method of the semiconductor package of the present embodiment will be described with reference to the semiconductor package 10 as an example.

The semiconductor package 10 can be produced by a method of mounting the semiconductor chip 2 on the organic substrate 1, and adhering the metal plate 3 to the organic substrate 1.

Either the time of mounting the semiconductor chip 2 on the organic substrate 1 or the time of adhering the metal plate 3 to the organic substrate 1 may be preceding, and the time of mounting the semiconductor chip 2 on the organic substrate 1 is preferably preceding from the standpoint of the productivity.

The method of mounting the semiconductor chip 2 on the organic substrate 1 is not particularly limited, and may be a known method. Specifically, examples thereof include a reflow process in which the semiconductor chip 2 and the electrode of the organic substrate 1 are positioned and temporarily fixed, and then heated to the melting point of solder constituting the bumps or higher, and a TCB (thermal compression bonding) process. The temperature in the reflow process is not particularly limited, as long as being the melting point of solder or higher, and for example, is in a range of 220 to 280° C. The temperature in the TCB process is not particularly limited, as long as being the melting point of solder or higher, and for example, is in a range of 280 to 330° C.

The semiconductor chip 2 may also be attached to the organic substrate 1 with a die bonding material, a bonding film, such as an anisotropic conductive film, and a bonding paste, such as a non-conductive paste.

Thereafter, the gap between the semiconductor chip 2 and the organic substrate 1 may be sealed with a liquid sealant. The surface of the semiconductor chip 2 may be sealed entirely or partially with a semiconductor sealant. The liquid sealant and the semiconductor sealant used may be known materials.

The method of adhering the metal plate 3 to the organic substrate 1 is preferably a method of using an adhesive.

The adhesive for adhering the metal plate 3 is preferably an adhesive having thermosetting property from the standpoint of the heat resistance. Examples of the thermosetting adhesive used include “KE-1867”, “KE-1285 (A/B)”, and “X-32-3126”, trade names, available from Shin-Etsu Chemical Co., Ltd.

In the case where the thermosetting adhesive is used, the metal plate 3 can be adhered to the organic substrate 1 in such a manner that the adhesive is coated on the adhesion surface of the metal plate 3 to be adhered to the organic substrate 1, and the surface having the adhesive coated thereon is laminated on the organic substrate 1, followed by heating under condition suitable for the adhesive.

### [Semiconductor Device]

The semiconductor device of the present embodiment is a semiconductor device including the semiconductor package of the present embodiment, and a motherboard mounting the semiconductor package.

The semiconductor package can be mounted on the motherboard, for example, by a method of bonding an electrode pad formed on the semiconductor package to the motherboard through a reflow process.

The semiconductor package of the present embodiment is suppressed in the change amount of warpage due to temperature, and therefore the change amount between the warpage amount at room temperature and the warpage amount at the reflow temperature in mounting on a motherboard can be kept low. Consequently, the semiconductor device of the present embodiment is excellent in connection reliability.

### EXAMPLES

The present embodiment will be described specifically with reference to examples below. However, the present embodiment is not limited to the examples.

### [Measurement Method of Average Thermal Expansion Coefficient of Metal]

The metal plate 3 used in the examples as a measurement specimen was measured for the surface displacement by the DIC (digital image correlation) method as an optional function of a shadow moire device (“TherMoire AXP”, trade name, available from Acrometrix, Thermo Fisher Scientific Inc.). The evaluation specimen was mounted on the device, and then measured continuously twice under the measurement condition of an average temperature rise rate of 15° C./min. The average value of the thermal expansion coefficient from 30° C. to 260° C. in the second measurement was designated as the value of the average thermal expansion coefficient of the metal.

### [Measurement Method of Average Thermal Expansion Coefficient of Organic Substrate 1 in Plane Direction]

The organic substrate 1 used in the examples as a measurement specimen was measured for the surface displacement by the DIC (digital image correlation) method as an optional function of a shadow moire device (“TherMoire AXP”, trade name, available from Acrometrix, Thermo Fisher Scientific Inc.). The evaluation specimen was mounted on the device to enable the measurement of the thermal expansion coefficient in the plane direction, and then measured continuously twice under the measurement condition of an average temperature rise rate of 22° C./min. The average value of the thermal expansion coefficient from 30° C. to 260° C. in the second measurement was designated as the value of the average thermal expansion coefficient in the plane direction of the organic substrate 1.

### [Measurement Method of Young's Modulus of Metal]

The metal constituting the metal plate 3 as a measurement specimen was subjected to a tensile test according to JIS Z2241 (2011) to provide a stress-strain curve, from which the gradient in the linear part in the elastic range is obtained and designated as the Young's modulus.

### [Measurement Method of Thermal Conductivity Coefficient of Metal]

A test piece formed of the metal constituting the metal plate 3 as a measurement specimen was measured for the thermal conductivity coefficient by the laser flash method according to JIS R1611 (2010).

### [Production of Semiconductor Package]

### Examples 1 to 4

The semiconductor package having the structure shown in FIGS. 1(a) and 1(b) was produced according to the following procedures.

An organic substrate 1 having the following structure (having a rectangular outline shape of 60 mm×60 mm in plan view and a thickness of 1.6 mm) (which may be hereinafter referred to as an “organic substrate 1(A)” was produced by using an insulating layer formed of the insulating layer-forming material shown in Table 1 as a core layer, and also using a buildup material (“GX92” trade name, available from Ajinomoto Co., Inc., thickness: 30 μm) (which may be hereinafter referred to as “Bu”), a copper foil (thickness: 18 μm or 12 μm), and a solder resist (“SR-7300” trade name, available from Showa Denko Materials Co., Ltd.) (which may be hereinafter referred to as “SR”).

SR (15 μm)/copper foil (18 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (12 μm)/core layer (800 to 900 μm)/copper foil (12 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (18 μm)/SR (15 μm)

The thicknesses in parentheses are the thicknesses of the layers before lamination.

Subsequently, at the center of one surface of the organic substrate 1(A), bumps provided on the circuit surface side of a silicon semiconductor chip 2 (having a rectangular outline shape of 25 mm×25 mm in plan view and a thickness of 0.725 mm) (which may be hereinafter referred to as a “semiconductor chip 2(A)”) were bonded by the TCB process to provide a semiconductor chip-mounted substrate. The gap between the semiconductor chip 2(A) and the organic substrate 1(A) was sealed with a liquid sealant (“CEL-C-3730 Series”, trade name, available from Showa Denko Materials Co., Ltd.).

As the metal plate 3 shown in FIGS. 1(a) and 1(b), a metal plate 3 formed of the material shown in Table 1 (having a rectangular outline shape of 60 mm×60 mm in plan view and a thickness of 2.5 mm) having an opening 4 (having a rectangular shape of 44 mm×44 mm in plan view) (which may be hereinafter referred to as a “metal plate 3(A)”) was prepared. The metal plate 3(A) had a rectangular frame form in plan view, and the width of the sides constituting the rectangular shape (i.e., the distance b in FIG. 2) was 8 mm.

On the region where the semiconductor chip 2(A) was not mounted on the surface having the semiconductor chip 2(A) mounted thereon of the semiconductor chip-mounted substrate, the metal plate 3(A) was adhered in such a manner that the semiconductor chip 2(A) was positioned at the center of the opening 4, and the positions of the edges in plan view of the metal plate 3(A) and the edges of the organic substrate 1(A) coincided with each other. At this time, the distance between the edge of the semiconductor chip 2(A) and the edge of an opening 4 (i.e., the distance a in FIG. 2) was 9.5 mm.

The metal plate 3(A) was adhered to the organic substrate 1(A) by using a thermosetting silicone based adhesive (“KE-1867”, trade name, available from Shin-Etsu Chemical Co., Ltd.) as an adhesive, which was cured by heating to 125° C. for 2 hours.

### Comparative Examples 1 to 4

A semiconductor package was produced in the same manner as in Examples 1 to 4 except using the kinds of the insulating layer-forming materials and the metal plate 3 shown in Table 1.

### Comparative Examples 5 to 8

A semiconductor package was produced in the same manner as in Examples 1 to 4 except using the kinds of the insulating layer-forming materials shown in Table 1 without the use of the metal plate 3.

### Examples 5 to 8

An organic substrate 1 having the following structure (having a rectangular outline shape of 100 mm×100 mm in plan view and a thickness of 1.6 mm) (which may be hereinafter referred to as an “organic substrate 1(B)” was produced by using an insulating layer formed of the insulating layer-forming material shown in Table 2 as a core layer. The kinds of the buildup material, the copper foil, and the solder resist were the same as in Example 1.

SR (15 μm)/copper foil (18 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (12 μm)/core layer (1,400 to 1,500 μm)/copper foil (12 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (18 μm)/Bu (30 μm)/Bu (30 μm)/copper foil (18 μm)/SR (15 μm)

Subsequently, at the center of one surface of the organic substrate 1(B), bumps provided on the circuit surface side of a silicon semiconductor chip 2 (having a rectangular outline shape of 50 mm×50 mm in plan view and a thickness of 0.725 mm) (which may be hereinafter referred to as a “semiconductor chip 2(B)”) were bonded by the reflow process to provide a semiconductor chip-mounted substrate. The gap between the semiconductor chip 2(B) and the organic substrate 1(B) was sealed with the same liquid sealant as in Example 1.

As the metal plate 3 shown in FIGS. 1(a) and 1(b), a metal plate 3 formed of the material shown in Table 2 (having a rectangular outline shape of 100 mm×100 mm in plan view and a thickness of 2.5 mm or a thickness of 2.0 mm for SUS 430) having an opening 4 (having a rectangular shape of 68 mm×68 mm in plan view) (which may be hereinafter referred to as a “metal plate 3(B)”) was prepared. The metal plate 3(B) had a rectangular frame form in plan view, and the width of the sides constituting the rectangular shape (i.e., the distance b in FIG. 2) was 16 mm.

On the region where the semiconductor chip 2(B) was not mounted on the surface having the semiconductor chip 2(B) mounted thereon of the semiconductor chip-mounted substrate, the metal plate 3(B) was adhered in such a manner that the semiconductor chip 2(B) was positioned at the center of the opening 4, and the positions of the edges in plan view of the metal plate 3(B) and the edges of the organic substrate 1(B) coincided with each other. At this time, the distance between the edge of the semiconductor chip 2(B) and the edge of the opening 4 (i.e., the distance a in FIG. 2) was 9.0 mm. The metal plate 3(B) was adhered to the organic substrate 1(B) by using the same adhesive under the same condition as in Example 1.

### Comparative Examples 9 and 10

A semiconductor package was produced in the same manner as in Examples 5 to 8 except using the kinds of the insulating layer-forming materials and the metal plate 3 shown in Table 2.

### Comparative Examples 11 and 12

A semiconductor package was produced in the same manner as in Examples 5 to 8 except using the kinds of the insulating layer-forming materials shown in Table 2 without the use of the metal plate 3.

### [Measurement of Warpage Amount]

The warpage of the semiconductor package was measured by the shadow moire method with a warpage measuring device with a heating mechanism, “TherMoire AXP”, trade name, available from Acrometrix, Thermo Fisher Scientific Inc. Specifically, the semiconductor package produced in each of the examples was heated from 25° C. to 260° C. or 245° C., and the three-dimensional shapes of the semiconductor package at 30° C. and 260° C. or 245° C. were obtained.

The three-dimensional shape thus obtained was analyzed separately for the “semiconductor chip non-mounted region” having no semiconductor chip mounted thereon shown by the hatched area in FIG. 3(a) and the “semiconductor chip mounted region” having the semiconductor chip mounted thereon shown by the hatched area in FIG. 3(b), and the absolute value of the difference between the warpage amount at 30° C. and the warpage amount at 260° C. or 245° C. was calculated and designated as the warpage change amount in each of the regions.

As for the warpage amounts in the regions, in the case where the region to be analyzed showed upward convex warpage when the surface having the semiconductor chip mounted thereon was directed upward, the distance from the lowest position thereof as the reference height (0 μm) to the most distant position thereof within the region was designated as the warpage amount for positive value. In the case where the region to be analyzed showed downward convex warpage, the distance from the highest position thereof as the reference height (0 μm) to the most distant position thereof within the region was designated as the warpage amount for negative value. The results are shown in Tables 1 and 2.

TABLE 1

| | | | Example | | | | Comparative Example | | |
|---|---|---|---|---|---|---|---|---|---|
| | | | 1 | 2 | 3 | 4 | 1 | 2 | 3 |
| Member | Organic | Kind of insulating | 705G | 795G | 705GLH | 795GLH | 705G | 795G | 705GLH |
| | substrate 1 | layer-forming material | | | | | | | |
| | | Thermal expansion | 12.1 | 10.7 | 8.5 | 7.7 | 12.1 | 10.7 | 8.5 |
| | | coefficient in plane | | | | | | | |
| | | direction of organic | | | | | | | |
| | | substrate 1 | | | | | | | |
| | | (ppm/° C.) | | | | | | | |
| | Metal | Kind of metal | Cu/W | Cu/W | Cu/W | Cu/W | Cu | Cu | Cu |
| | plate 3 | Thermal expansion | 8.4 | 8.4 | 8.4 | 8.4 | 16.4 | 16.4 | 16.4 |
| | | coefficient of metal | | | | | | | |
| | | (ppm/° C.) | | | | | | | |
| Evaluation | Semiconductor | Warpage amount | 107 | 84 | 46 | 36 | 103 | 96 | 63 |
| result | chip mounted | at 30° C. (μm) | | | | | | | |
| | region | Warpage amount | −25 | −33 | −3 | −6 | −15 | −18 | 4 |
| | | at 260° C. (μm) | | | | | | | |
| | | Warpage change | 132 | 117 | 49 | 42 | 117 | 114 | 59 |
| | | amount *1 (μm) | | | | | | | |
| | Semiconductor | Warpage amount | −49 | −29 | 19 | 21 | 10 | 34 | 81 |
| | chip non- | at 30° C. (μm) | | | | | | | |
| | mounted | Warpage amount | 19 | 31 | 24 | 23 | −91 | −81 | −90 |
| | region | at 260° C. (μm) | | | | | | | |
| | | Warpage change | 68 | 60 | 6 | 2 | 101 | 115 | 171 |
| | | amount *1 (μm) | | | | | | | |

| | | | Comparative Example | | | | |
|---|---|---|---|---|---|---|---|
| | | | 4 | 5 | 6 | 7 | 8 |
| Member | Organic | Kind of insulating | 795GLH | 705G | 795G | 705GLH | 795GLH |
| | substrate 1 | layer-forming material | | | | | |
| | | Thermal expansion | 7.7 | 12.1 | 10.7 | 8.5 | 7.7 |
| | | coefficient in plane | | | | | |
| | | direction of organic | | | | | |
| | | substrate 1 | | | | | |
| | | (ppm/° C.) | | | | | |
| | Metal | Kind of metal | Cu | no metal | no metal | no metal | no metal |
| | plate 3 | | | plate | plate | plate | plate |
| | | Thermal expansion | 16.4 | — | — | — | — |
| | | coefficient of metal | | | | | |
| | | (ppm/° C.) | | | | | |
| Evaluation | Semiconductor | Warpage amount | 51 | 121 | 97 | 20 | 57 |
| result | chip mounted | at 30° C. (μm) | | | | | |
| | region | Warpage amount | 22 | −33 | −20 | −8 | 23 |
| | | at 260° C. (μm) | | | | | |
| | | Warpage change | 29 | 153 | 117 | 28 | 34 |
| | | amount *1 (μm) | | | | | |
| | Semiconductor | Warpage amount | 77 | −99 | −92 | −27 | −26 |
| | chip non- | at 30° C. (μm) | | | | | |
| | mounted | Warpage amount | −157 | −23 | −25 | −18 | −39 |
| | region | at 260° C. (μm) | | | | | |
| | | Warpage change | 234 | 76 | 68 | 9 | 14 |
| | | amount *1 (μm) | | | | | |

*1 absolute value of difference between warpage amount at 30° C. and warpage amount at 260° C.

TABLE 2

| | | | Example | | | | Comparative Example | | | |
|---|---|---|---|---|---|---|---|---|---|---|
| | | | 5 | 6 | 7 | 8 | 9 | 10 | 11 | 12 |
| Member | Organic | Kind of insulating | 705GLH | 705GLH | 795GLH | 795GLH | 705GLH | 795GLH | 705GLH | 795GLH |
| | substrate 1 | layer-forming material | | | | | | | | |
| | | Thermal expansion | 11.8 | 11.8 | 10.6 | 10.6 | 11.8 | 10.6 | 11.8 | 10.6 |
| | | coefficient in plane | | | | | | | | |
| | | direction of organic | | | | | | | | |
| | | substrate 1 | | | | | | | | |
| | | (ppm/° C.) | | | | | | | | |
| | Metal | Kind of metal | Cu/Mo | SUS430 | Cu/Mo | SUS430 | Cu | Cu | no metal | no metal |
| | plate 3 | | | | | | | | plate | plate |
| | | Thermal expansion | 11.5 | 10.4 | 11.5 | 10.4 | 16.4 | 16.4 | — | — |
| | | coefficient of metal | | | | | | | | |
| | | (ppm/° C.) | | | | | | | | |
| Evaluation | Semiconductor | Warpage amount | 124 | 171 | 109 | 123 | 129 | 105 | 276 | 264 |
| result | chip mounted | at 30° C. (μm) | | | | | | | | |
| | region | Warpage amount | 31 | −20 | 26 | 25 | −50 | 83 | −88 | −48 |
| | | at 245° C. (μm) | | | | | | | | |
| | | Warpage change | 93 | 191 | 83 | 98 | 179 | 22 | 364 | 312 |
| | | amount *2 (μm) | | | | | | | | |
| | Semiconductor | Warpage amount | 96 | 65 | 37 | 31 | 99 | 126 | −337 | −329 |
| | chip non- | at 30° C. (μm) | | | | | | | | |
| | mounted | Warpage amount | −105 | −78 | −74 | −60 | −334 | −313 | 31 | 8 |
| | region | at 245° C. (μm) | | | | | | | | |
| | | Warpage change | 201 | 143 | 111 | 91 | 433 | 439 | 368 | 337 |
| | | amount *2 (μm) | | | | | | | | |

*2 absolute value of difference between warpage amount at 30° C. and warpage amount at 245° C.

The details of the kinds of the insulating layer-forming materials and the metal plates shown in Tables 1 and 2 are as follows.

### <Insulating Layer-Forming Material>

705G: copper-clad laminate, “MCL-E-705G”, trade name, available from Showa Denko Materials Co., Ltd.

795G: copper-clad laminate, “MCL-E-795G”, trade name, available from Showa Denko Materials Co., Ltd.

705GLH: copper-clad laminate, “MCL-E-705G (LH)”, trade name, available from Showa Denko Materials Co., Ltd.

795GLH: copper-clad laminate, “MCL-E-795G (LH)”, trade name, available from Showa Denko Materials Co., Ltd.

### <Metal Plate>

Cu/W: alloy of copper and tungsten (copper content: 20% by mass, tungsten content: 80% by mass), Young's modulus: 330 GPa, thermal conductivity coefficient: 200 W/m·K

Cu: pure copper, Young's modulus: 120 GPa, thermal conductivity coefficient: 394 W/m·K

Cu/Mo: alloy of copper and molybdenum (copper content: 60% by mass, molybdenum content: 40% by mass), Young's modulus: 170 GPa, thermal conductivity coefficient: 275 W/m·K

SUS430: ferrite-based stainless steel having components shown in JIS G4303 (2012), Young's modulus: 200 GPa, thermal conductivity coefficient: 30 W/m·K

It is understood from the results shown in Table 1 that the semiconductor packages of Examples 1 to 4 of the present embodiment can be reduced in warpage change amount in the semiconductor chip non-mounted region, as compared to the semiconductor packages of Comparative Examples 1 to 8. It is also understood that the warpage change amount in the semiconductor chip mounted region is not largely influenced in the semiconductor packages of Examples 1 to 4 of the present embodiment. Similarly, it is understood from the results shown in Table 2 that the semiconductor packages of Examples 5 to 8 of the present embodiment can be reduced in warpage change amount in the semiconductor chip non-mounted region, as compared to the semiconductor packages of Comparative Examples 9 to 12.

### INDUSTRIAL APPLICABILITY

The semiconductor package of the present embodiment is reduced in the change amount of warpage due to temperature, and therefore is suitable particularly for the purpose of electronic components including a large organic substrate.

### REFERENCE SIGN LIST

1: Organic substrate having circuit
2: Semiconductor chip
3: Metal plate
4: Opening
10: Semiconductor package
a, b: distance

1. A semiconductor package comprising
an organic substrate having a circuit,
a semiconductor chip that is mounted on a part of one surface of the organic substrate, and is electrically connected to the circuit, and
a metal plate that is adhered to the one surface of the organic substrate in at least a part of a region where the semiconductor chip is not mounted, and is not electrically connected to the circuit,
a metal constituting the metal plate having an average thermal expansion coefficient at 30 to 260° C. of 3 to 15 ppm/° C.

2. The semiconductor package according to claim 1, wherein the metal constituting the metal plate is one or more kind selected from the group consisting of an alloy of copper and tungsten, an alloy of copper and molybdenum, and a stainless steel.

3. The semiconductor package according to claim 2, wherein the alloy of copper and tungsten has a content of tungsten of 65 to 90% by mass.

4. The semiconductor package according to claim 2, wherein the alloy of copper and molybdenum has a content of molybdenum of 20 to 60% by mass.

5. The semiconductor package according to claim 2, wherein the stainless steel has a content of chromium of 10 to 25% by mass.

6. The semiconductor package according to claim 1, wherein the metal constituting the metal plate has a Young's modulus of 150 GPa or more.

7. The semiconductor package according to claim 1, wherein the metal constituting the metal plate has a thermal conductivity coefficient of 20 W/m·K or more.

8. The semiconductor package according to claim 1, wherein the metal plate has a thickness of 0.5 to 5 mm.

9. The semiconductor package according to claim 1, wherein the organic substrate has an area in plan view of 900 mm² or more.

10. The semiconductor package according to claim 1, wherein the organic substrate has a rectangular outline shape in plan view, and four edges of the organic substrate having a rectangular outline shape each have a length of 30 mm or more.

11. The semiconductor package according to claim 1, wherein the metal plate has an opening in plan view, and the semiconductor chip is mounted on at least a part of the one surface of the organic substrate exposed through the opening.

12. The semiconductor package according to claim 11, wherein the metal plate has a rectangular frame form in plan view.

13. A semiconductor device comprising the semiconductor package according to claim 1, and a motherboard mounting the semiconductor package.
